(19) United States
(12) Patent Application Publication
(10) Pub. No.: US 2010/0128190 A1
(43) Pub. Date: May 27, 2010

(54) Liquid Crystal Display and Manufacturing Method of the Same

(76) Inventors: Bo-Kyoung Ahn, Incheon (KR); Bo-Sung Kim, Seoul (KR); Young-Min Kim, Yongin-si (KR); Nam-Ok Jung, Suwon-si (KR); Seung-Hwan Cho, Suwon-si (KR)

Correspondence Address: F. CHAU & ASSOCIATES, LLC, 130 WOODBURY ROAD, WOODBURY, NY, 11797, US

(21) Appl. No.: 12/431,503

(22) Filed: Apr. 28, 2009

(30) Foreign Application Priority Data
Nov. 27, 2008 (KR) 10-2008-0118889

(51) Int. Cl. G02F 1/1368; H01L 21/336

(52) U.S. Cl. 349/43; 438/30; 257/E33.053; 257/E21.412

(57) ABSTRACT

Disclosed is a liquid crystal display including a first substrate, a second substrate facing the first substrate, a thin film transistor formed on the first substrate and including a semiconductor layer, a convex pattern formed on the semiconductor layer and provided at a side surface thereof with a concave-convex section, and a liquid crystal layer interposed between the first and second substrates.

### CROSS-REFERENCE TO RELATED APPLICATION

This application claims priority from Korean Patent Application No. 2008-118889 filed on Nov. 27, 2008, the contents of which are herein incorporated by reference in their entirety.

### BACKGROUND OF THE INVENTION

1. Field of the Invention

The present disclosure is directed to a liquid crystal display (LCD) having a thin film transistor and a method of manufacturing the same. More particularly, the present disclosure is directed to a liquid crystal display having a convex pattern, which protects a semiconductor layer of a thin film transistor, and a method of manufacturing the same.

2. Description of the Related Art

Among flat panel display types, liquid crystal displays (LCDs) are popular due to ease of mass production, simple driving scheme and high quality images thereof.

An LCD includes a liquid crystal layer interposed between two transparent substrates that drive the liquid crystal layer to adjust transmittance of light passing through each pixel, thereby displaying a desired image.

The LCD includes a thin film transistor in each pixel to drive the liquid crystal layer. The LCD may use an organic semiconductor layer as a semiconductor layer of the thin film transistor instead of a silicon layer. A thin film transistor employing an organic semiconductor layer is referred to as an organic thin film transistor (OTFT). A thin film transistor requires a protective pattern to protect the semiconductor layer. However, since a conventional photolithography process is complicated and requires an expensive mask to form the protective pattern, the photolithography process is inefficient in terms of manufacturing cost and time.

In this regard, an inkjet process has been developed to improve the conventional exposure process. However, since the ink used for inkjet processes has a low viscosity, a sufficiently thick protective pattern may not be formed.

### SUMMARY OF THE INVENTION

Embodiments of the present invention provide an LCD capable of simplifying a manufacturing process.

Further, embodiments of the present invention provide a method of manufacturing an LCD including a thin film transistor.

In one aspect of the present invention, a liquid crystal display includes a first substrate, a second substrate, a thin film transistor, a convex pattern, and a liquid crystal layer. The second substrate faces the first substrate. The thin film transistor is formed on the first substrate and includes a semiconductor layer. The convex pattern is formed on the semiconductor layer. The convex pattern comprises a concave-convex section at a side surface thereof. The liquid crystal layer is interposed between the first and second substrates.

The thin film transistor includes a gate electrode, a gate insulating layer, a source electrode, a bank, and the semiconductor layer. The gate electrode is formed on the first substrate. The gate insulating layer is formed on the gate electrode and the first substrate. The source electrode and the drain electrode are formed on the gate insulating layer. The source electrode and the drain electrode are spaced apart from each other about the gate electrode. The bank is formed on the gate insulating layer and the source and drain electrodes. The bank has an opening on a predetermined region of the source and drain electrodes. The remaining region on the source and drain electrodes is covered with the bank. The semiconductor layer is formed on the predetermined region of the source and drain electrodes exposed by the opening to form a channel between the source and gate electrodes.

The bank further includes a contact hole to expose a portion of the remaining region of the drain electrode. A pixel electrode, which is connected to the drain electrode through the contact hole, is formed on the bank.

In addition, the second substrate includes a common electrode forming an electric field together with the pixel electrode.

The convex pattern fills the opening formed on the semiconductor layer, and may be a protrusion to distort the electric field formed by the pixel electrode and the common electrode. In this case, the common electrode may be formed thereon with a plurality of slits to distort the electric field, and, if necessary, may include protrusions instead of the slits.

The convex pattern may be a spacer maintaining a cell gap between the first and second substrates.

In another aspect of the present invention, a method of manufacturing the liquid crystal display is performed as follows. A first substrate and a second substrate facing the first substrate are prepared, and a thin film transistor including a semiconductor layer is formed on the first substrate. Thereafter, a convex pattern is formed on the semiconductor layer, and a liquid crystal layer is interposed between the first and second substrates.

The convex pattern is formed on the semiconductor layer through an ink-jet scheme. According to the ink-jet scheme, a first plurality of ink droplets are dropped, and the ink droplets are half-baked, and then, a second plurality of ink droplets are dropped and half-baked. Such a manner of additionally dropping and half-baking ink droplets is repeated more than one time. The half-bake may be performed as a photo-bake by irradiation of light or a thermal-bake at a room temperature.

To form the thin film transistor, a gate electrode is formed on the first substrate. A source electrode and a drain electrode spaced apart from each other about the gate electrode are formed on the first substrate formed with the gate electrode. Then, a gate insulating layer is formed on the surface of the first substrate Next, a bank is formed on the gate insulating layer and the source and drain electrodes. The bank has an opening, which is formed at a predetermined region of the source and drain electrodes. Then, the semiconductor layer is formed on the source and drain electrodes exposed by the opening to form a channel between the source and gate electrodes.

In another aspect of the present invention, a method of manufacturing the liquid crystal display is performed as follows. A thin film transistor including a semiconductor layer is formed. A convex pattern is formed on the semiconductor layer. The forming of the convex pattern includes dropping a plurality of ink droplets on the semiconductor layer through an ink-jet scheme, baking the plurality of ink droplets to form a pattern; and repeating the steps of dropping a plurality of ink droplets and the half-baking the dropped ink droplets to form a pattern. The number of droplets in each plurality of ink droplets may be varied.

According to an embodiment of the present invention, the thickness of a convex pattern can be adjusted by simply controlling the inkjet process regardless of external factors such as surface energy of a bank or the ink.

Further, in a method according to an embodiment of the present invention, a protective pattern that protects the semiconductor layer of the thin film transistor can be formed through a simplified process without employing a photolithography process.

Furthermore, when the convex pattern is formed using a method according to an embodiment of the present invention, the convex pattern may also serve as a spacer to maintain a cell gap between the first substrate and the second substrate, or a plurality of protrusions to distort an electric field applied to the liquid crystal layer.

### BRIEF DESCRIPTION OF THE DRAWINGS

FIG. 1 is a plan view showing a part of an LCD according to an embodiment of the present invention.

FIG. 2 is a cross sectional view showing an LCD according to the embodiment of FIG. 1.

FIGS. 3A to 3D are cross sectional views showing a method of forming a convex pattern according to an embodiment of the present invention.

FIGS. 4A to 4C are cross sectional views showing various shapes of a convex pattern, in which FIG. 4A shows the convex pattern formed by dropping ink droplets three times while fixing the number of the ink droplets for one time, FIG. 4B shows the convex pattern formed by dropping the ink droplets three times while reducing the number of the ink droplets for one time, and FIG. 4C shows the convex pattern formed by dropping the ink droplets three times while increasing the number of ink droplets for one time, respectively.

FIGS. 5A to 5C are graphs showing heights of a convex pattern formed on a substrate through a conventional method and a method according to an embodiment of the present invention.

FIG. 6 is a sectional view showing a convex pattern serving as a spacer to maintain a cell gap between a first substrate and a second substrate according to another embodiment of the present invention.

FIG. 7 is a sectional view showing a convex pattern serving as an electric field distortion member according to another embodiment of the present invention; and

FIG. 8 is a sectional view showing a convex pattern serving as an electric field distortion member according to another embodiment of the present invention.

### DETAILED DESCRIPTION OF EXEMPLARY EMBODIMENTS

Hereinafter, a display apparatus according to an embodiment of the present invention will be described with reference to accompanying drawings.

It should be understood that the present invention is not limited to embodiments shown in the appended drawings but includes all modifications, equivalents and alternatives within the sprit and scope of the present invention as defined in the following claims. In the drawings, the same reference numbers are used to designate the same elements. As used herein, the expression, “one layer (film) is formed (disposed) ‘on’ another layer (film)” includes not only a case wherein the two layers (films) are in contact with each other but also a case wherein an additional layer (film) is present between the two layers (films).

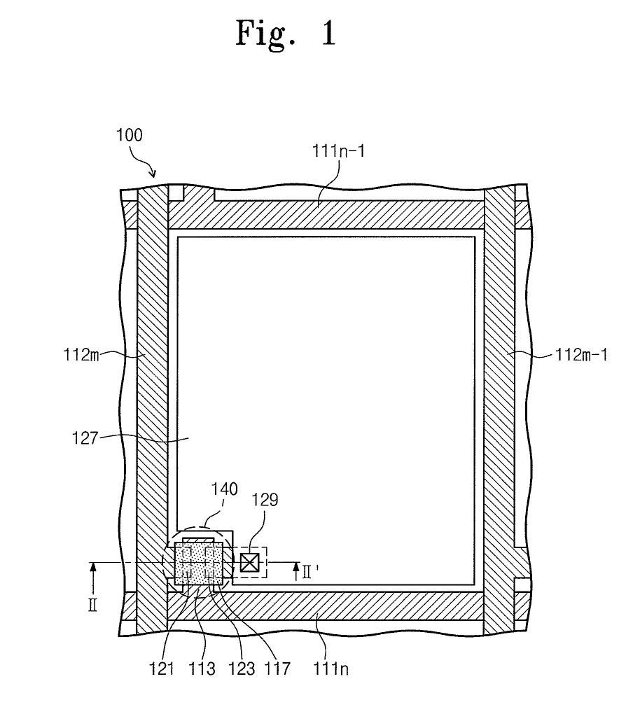

FIG. 1 is a plan view showing a part of an LCD according to an embodiment of the present invention.

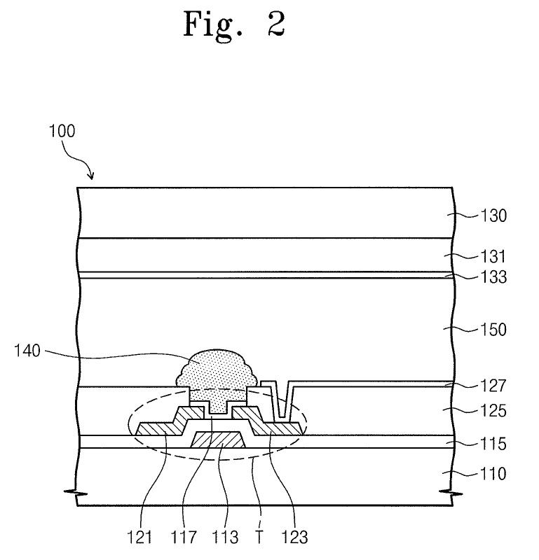

FIG. 2 is a cross sectional view taken along line II-II′ of a substrate shown in FIG. 1 to illustrate an LCD according to an embodiment of the present invention.

Although N gate lines and M data lines cross each other to form M×N pixels on a substrate of the liquid crystal display, an (m×n)^{th} pixel is only illustrated in the drawings for the purpose of convenience of explanation.

As shown in the drawings, a liquid crystal display 100 includes a first substrate 110, a second substrate 130 and a liquid crystal layer 150. The first substrate 110 and the second substrate 130 are prepared in the form of transparent insulating substrates and face each other. The liquid crystal layer 150 is formed between the two substrates 110 and 130.

An n^{th} gate line 111n and an m^{th} data line 112m are formed on the first substrate 110 in the longitudinal and transverse directions to define a (m×n)^{th} pixel area. A thin film transistor T serving as a switching element is formed at an intersection between the n^{th} gate line 111n and the m^{th} data line 112m, and a pixel electrode 127 is formed in the pixel area in connection with the thin film transistor T such that the pixel electrode 127 drives the liquid crystal layer 150 in cooperation with a common electrode 133 of the second substrate 130.

The thin film transistor T includes a gate electrode 113 forming a part of the n^{th} gate line 111n, a source electrode 121 connected to the m^{th} data line 112m and a drain electrode 123 connected to the pixel electrode 127. In addition, the thin film transistor T includes a gate insulating layer 115, which insulates the gate electrode 113 and the source and drain electrodes 121 and 123, and a semiconductor layer 117, which forms a conductive channel between the source electrode 121 and the drain electrode 123 when a gate voltage is applied to the gate electrode 113. A convex pattern 140 serving as a protective pattern is formed on the semiconductor layer 117 to protect the semiconductor layer 117.

In this case, a part of the source electrode 121 is connected to the m^{th} data line 112m to serve as a part of the m^{th} data line 112, and a part of the drain electrode 123 extends toward the pixel area and is electrically connected to the pixel electrode 127 via a contact hole 129 formed through a bank 125. Although the pixel electrode 127 is not formed on the convex pattern 140 in the present embodiment, if necessary, the pixel electrode 127 can be formed on the convex pattern 140 in other embodiments of the invention.

As shown in FIG. 2, the gate electrode 113 is formed on the first substrate 110, and the source electrode 121 and the drain electrode 123 are formed on the gate electrode 113 while facing each other about the gate electrode 113.

The bank 125 is formed over the first substrate 110 over which the source electrode 121 and the drain electrode 123 are formed, and the bank 125 has an opening formed at a predetermined region above the gate electrode 113. That is, the opening is formed in a region corresponding to a space between the source electrode 121 and the drain electrode 123 and a part of a region above the source electrode 121 and the drain electrode 123. The opening exposes part of the surfaces of the source electrode 121 and the drain electrode 123.

The semiconductor layer 117 is provided in the form of an island in the opening of the bank 125. The semiconductor layer 117 makes contact with the source electrode 121 and the drain electrode 123 exposed by the opening. The bank 125 has a height greater than that of the semiconductor layer 117 and defines a position of the semiconductor layer 117 in the opening.

The semiconductor layer 117 may include various materials including nano-scale particles and organic materials available for semiconductor materials in addition to amorphous silicon and polycrystalline silicon. Although the semiconductor layer 117 may include an organic semiconductor material, embodiments of the present invention are not limited thereto.

In the case that the semiconductor layer 117 includes an organic semiconductor material, the semiconductor layer 117 may include at least one of pentacene, tetracene, anthracene, naphthalene, alpha-6-thiophene (α-6T), perylene and derivatives of perylene, rubrene and derivatives of rubrene, coronene and derivatives of coronene, perylene tetracarbocylic diimide and derivatives of perylene tetracarbocylic diimide, perylene tetracarboxylic dianhydride and derivative of perylene tetracarboxylic dianhydride, polythiophen and derivatives of polythiophen, polyparaphenylenevinylene and derivatives of polyparaphenylenevinylene, polyfluoren and derivatives of polyfluoren, polythiophenvinylene and derivatives of polythiophenvinylene, polyparaphenylene and derivatives of polyparaphenylene, polythiophen-heterocycle aromatic copolymer and derivatives of polythiophen-heterocycle aromatic copolymer, oligoacene of naphthalene and derivatives of oligoacene of naphthalene, oligothiophene of α-5T and derivatives of oligothiophene of α-5T, phthalocyanine containing or not containing metal and derivatives of phthalocyanine containing or not containing metal, pyromellitic dianhydride and derivatives of pyromellitic dianhydride, pyromellitic diimide and derivates of pyromellitic diimide, perylenetetracarboxylic acid dianhydride and derivates of perylenetetracarboxylic acid dianhydride, naphthalene tetracarboxylic acid diimide and derivates of naphthalene tetracarboxylic acid diimide, and naphthalene tetracarboxylic acid dianhydride and derivates of naphthalene tetracarboxylic acids dianhydride.

The convex pattern 140 is formed on the semiconductor layer 117 while completely surrounding the semiconductor layer 117 and covering the opening. The convex pattern 140 may be made of an organic layer or an inorganic layer, and embodiments of the present invention are not limited thereto. The convex pattern 140 may include an organic polymer, which can be prepared in the form of a liquid phase ink suitable for an inkjet process. In particular, the organic polymer may be baked by light or heat.

The convex pattern 140 protrudes upward. In addition, the convex pattern 140 has a concave-convex section, which is formed at a side surface thereof. The concave-convex section is formed along a finning point of the side surface of the convex pattern 140 and has a ring shape.

A color filter 131 is formed on the second substrate 130 to represent a red color, a green color and a blue color corresponding to each pixel. The common electrode 133 is formed on the color filter 131 to form an electric field in cooperation with the pixel electrode 127 of the first substrate 110.

In a liquid crystal display 110 having the above structure, a common voltage serving as a reference voltage is provided to the common electrode 133 and the thin film transistor T provides a pixel signal of the m^{th} data line 112m to the pixel electrode 127 in response to a scan signal of the n^{th} gate line 111n, thereby driving the liquid crystals. As a result, the electric field is formed between the common electrode 133 and the pixel electrode 127, so the liquid crystal molecules are tilted due to the electric field, thereby varying light transmission such that images can be displayed.

According to an embodiment of the present invention, a method of manufacturing a liquid crystal display is provided. A method of forming a convex pattern on the substrate according to an embodiment of the present invention will explained and then a method of manufacturing a liquid crystal display according to an embodiment of the present invention will be explained.

A convex pattern according to the present embodiment is formed through an inkjet scheme. The inkjet scheme substitutes for a photolithography scheme. However, if a conventional inkjet scheme is employed, since the ink used in the inkjet process has a viscosity in the range of several cP to several tens cP, application of the ink is limited. In the case of forming a film by using an inkjet scheme, a thickness of the film is determined by various factors, such as the existence of the bank used to confine the ink, the height of the bank, the viscosity of the ink, the surface tension of the ink and adjacent materials, the solid powder content of the ink, and the difference in surface energy between the substrate and the ink. The most important factor among them is the viscosity of ink used in the inkjet process. If the viscosity of ink is lower than a certain value, the ink is spread laterally, and the resultant film may insufficiently thick. For example, even though the semiconductor layer (which serves as a channel area) of the thin film transistor requires a protective pattern having a sufficient thickness to prevent oxygen or moisture introduced from the outside from serving as a trap for electrons, an inkjet scheme cannot form a protective pattern with a sufficiently large thickness. According to an embodiment of the present invention, a method of increasing the thickness of the film is provided by controlling the inkjet process in a state that the material and the substrate are selected.

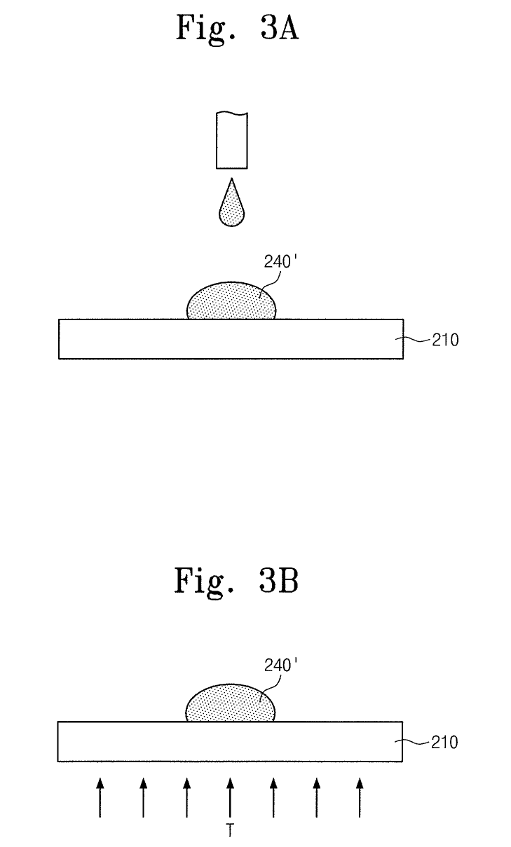

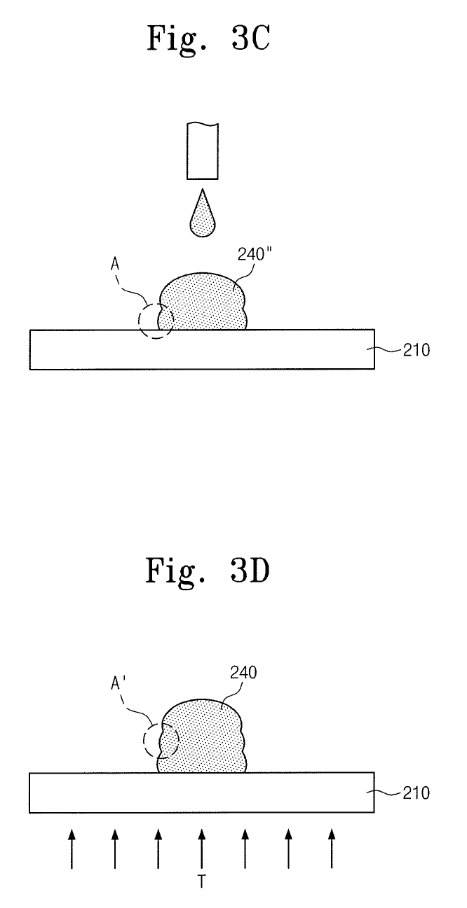

FIGS. 3A to 3D are cross sectional views showing a method of forming a convex pattern according to an embodiment of the present invention.

As shown in the drawings, a nozzle configured to jet ink is disposed above a substrate 210 on which a pattern is later formed. A first plurality of ink droplets are dropped from the nozzle to form a first pattern 240′ (see FIG. 3A). Although the ink droplet is referred to as ‘ink’, the ink is not intended to have a specific color. The ink droplet represents a material of the convex pattern prepared in the liquid phase.

The number of the ink droplets that are dropped can be adjusted under specific conditions and about 100 to about 150 ink droplets may be dropped. The first ink droplets are not spread over the entire surface of the substrate 210 but are conglomerated while forming a predetermined contact angle at a finning point at which the surface tension between the substrate 210 and the first ink are in equilibrium.

Subsequently, the first pattern 240′ is baked by applying heat (T) or light (not shown) to the substrate on which the first pattern 240′ is formed. The baking process can be performed by means of a half-bake. The half-bake corresponds to a process in which the ink is not completely cured, but is cured into an immobile state. In this case, a surface of the ink is partially cured and the inside of the ink is not cured (see FIG. 3B).

Then, a second plurality of ink droplets are dropped on the first pattern 240′ which has been subject to the half-bake (see FIG. 3C). The number of the second ink droplets can be adjusted and may be about 120 to about 150 droplets.

As the second ink droplets are dropped on the first pattern 240′, which has been subject to the half-bake, the second ink droplets accumulate on the first pattern 240, thereby forming a second pattern 240″. An upper part of the first pattern 240′ makes contact with the second pattern 240″ and a portion of the half-bake first ink making contact with the second ink is dissolved by the newly dropped second ink. Accordingly, a boundary of the first pattern 240′ making contact with the second ink disappears, and a concave-convex section (A) having a band shape is formed at a side surface portion of the first pattern 240′, which does not make contact with the second ink, along a point which the substrate 210 and the first ink meet.

If necessary, heat or light can be applied to an upper part of the second pattern 240″ and then a third plurality of ink droplets are dropped. The baking process can be performed by means of a half-bake. When the second ink droplets are dropped and the second pattern 240″ is formed, a boundary between the first pattern 240′ and the second pattern 240″, that is, a joining portion of the first pattern 240′ and the second pattern 240″, serves as a finning point, and the outer surface of the second pattern 240″ is left in the form of a band along the finning point, so that another concave-convex section (A′) is formed.

Finally, the structure formed through the above process is subject to a post-bake, thereby forming a convex pattern 240 (see 3D). The half-bake or the post-bake can be performed by applying heat at room temperature or by irradiating light.

The process of dropping ink droplets, performing the half-bake, and dropping more ink droplets, can be repeated several times. If the process is repeated several times, a pattern having a height greater than a width thereof can be formed.

In addition, according to the above method according to an embodiment of the invention of forming the convex pattern, the convex pattern can be formed in various shapes. For example, the shapes of convex patterns can be varied by adjusting the number of ink droplets.

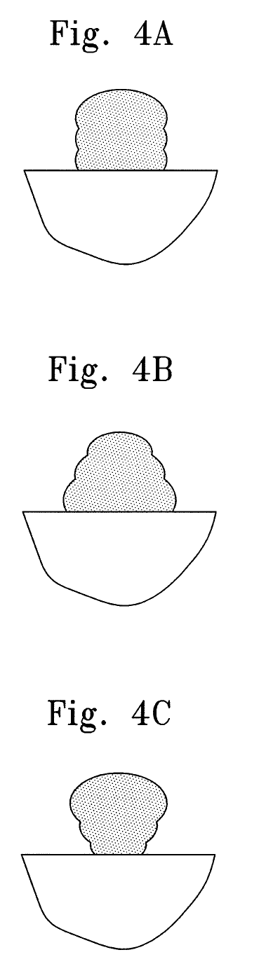

FIGS. 4A to 4C are cross sectional views showing various shapes of a convex pattern, in which FIG. 4A shows the convex pattern formed by dropping sets of ink droplets three times while fixing the number of the ink droplets for each drop time, FIG. 4B shows the convex pattern formed by dropping the ink droplets three times while reducing the number of the ink droplets for each drop time, and FIG. 4C shows the convex pattern formed by dropping the ink droplets three times while increasing the number of ink droplets for each drop time, respectively. The number of drop times and the number of droplets dropped each time may be adjusted. For example, FIG. 4B shows that a convex pattern having a protrusion upward may be formed by reducing the number of droplets for each drop time.

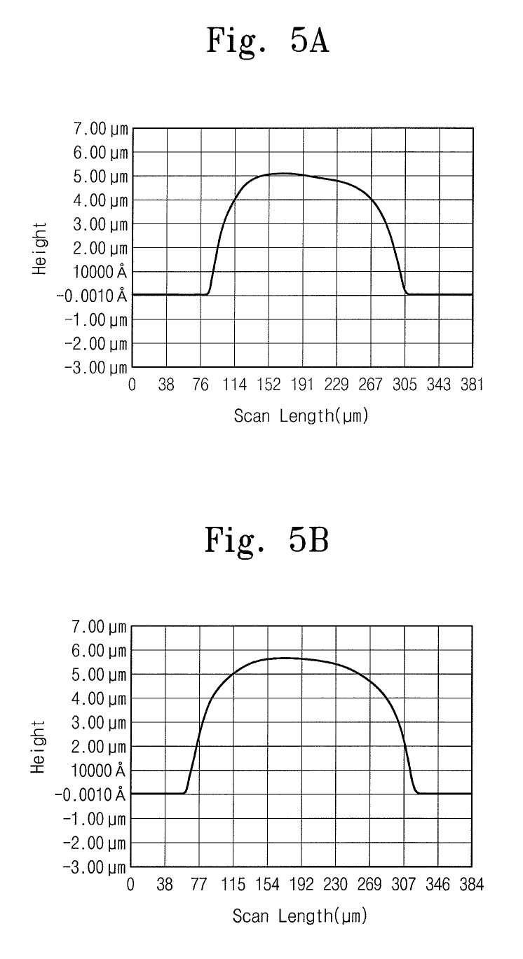

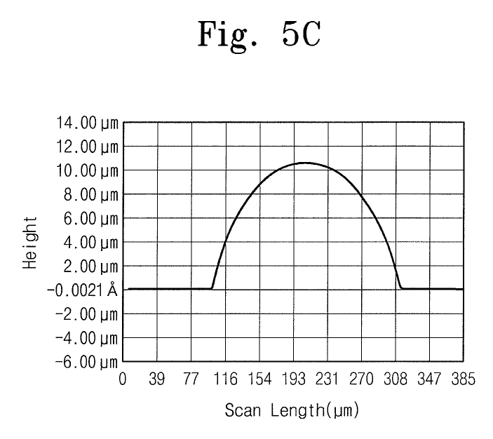

FIGS. 5A to 5C are graphs showing heights of a convex pattern formed on a substrate by using a conventional method and a method according to an embodiment of the present invention.

Referring to the drawings, FIG. 5A shows a height of a convex pattern formed by dropping 120 ink droplets for one time, in which the convex pattern has a height of about 4.94 μm. FIG. 5B shows a height of a convex pattern formed by dropping 240 ink droplets for one time, in which the convex pattern has a height of about 5.60 μm. FIG. 5C shows a height of a convex pattern formed by dropping ink droplets two times, in which 120 ink droplets are dropped one time and are subject to the half-bake, and then 120 ink droplets are dropped again. In this case, the convex pattern has a height of about 10.58 μm.

It should be noticed that the height of the pattern is insubstantially increased from a first case in which the 120 ink droplets are dropped at one time to a second case in which the 240 ink droplets are dropped at one time, even though the number of the ink droplets has doubled. That is, even though the amount of ink has increased, the height of the convex pattern has not substantially increased, but rather the width of the convex pattern has increased. On the other hand, when the convex pattern is formed according to an embodiment of the present invention, the width of the convex pattern is insubstantially changed, but the height of the convex pattern is approximately doubled. According to an inkjet method of an embodiment of the present invention, a pattern having the height greater than the width can be formed.

Hereinafter, a method of manufacturing a liquid crystal display using a convex pattern according to an embodiment of the invention will be described with reference to FIGS. 1 and 2.

According to an embodiment of the present invention, a liquid crystal display is manufactured as follows.

The first substrate 110 and the second substrate 130 facing the first substrate 110 are prepared, the thin film transistor T including the semiconductor layer 117 is formed on the first substrate 130, and then the liquid crystal layer 150 is formed between the two substrates 110 and 130.

To form the thin film transistor T on the first substrate 110, the n^{th} gate line 111n and the gate electrode 113 are formed on the substrate 110. In this case, the n^{th} gate line 111n and the gate electrode 130 are formed by depositing a first conductive layer on the entire surface of the substrate 110 and then patterning the first conductive layer through a photolithography process.

Then, the gate insulating layer 115 is formed on the entire surface of the substrate on which the n^{th} gate line 111n is formed. After that, a second conductive layer is formed on the entire surface of the gate insulating layer 115 and a photolithography process is performed on the second conductive layer, thereby forming the source electrode 121 and the drain electrode 123 spaced apart from the source electrode 121.

After that, insulating material is deposited on the entire surface of the substrate 110 over which the source electrode 121 and the drain electrode 123 are formed, and the bank 125 is patterned through a photolithography process. When the bank 125 is patterned, an opening and a contact hole are formed. The opening exposes a portion of the source electrode 121 and the drain electrode 123 and a space between the source and drain electrodes 121 and 123, and the contact hole exposes the remaining of the drain electrode 123.

The bank 125 includes an organic layer and, if necessary, the bank 125 can be subject to a plasma treatment, for example, using fluorine to change the surface energy of the bank 125. The energy difference between a surface of the bank 125 and the ink increases corresponding to the surface energy of the bank 125. If the surface energy difference increases, the contact angle formed when the convex pattern is made increases, thereby increasing the possibility of filling the opening with the dropped ink while preventing the dropped ink from spreading outward.

After treating the bank 125, the semiconductor layer 117 is formed through various schemes including an inkjet scheme or a photolithography scheme.

Then, ink droplets are dropped in the opening, in which the semiconductor layer 117 is formed, through the inkjet scheme, and the half-bake is performed with respect to the ink droplets. Subsequently, more ink droplets are dropped and the final half-bake is performed, thereby forming the convex pattern 140.

A transparent conductive material is deposited on the entire surface of the first substrate 110 and then selectively patterned through a photolithography process, thereby forming the pixel electrode 127, which is electrically connected to the drain electrode 123 through the contact hole.

The color filter 131 is formed on the second substrate 130 through a photolithography or printing process. The common electrode 133 is formed by depositing a transparent conductive material on the color filter 131.

The first and second substrates 110 and 130 prepared through the above process according to an embodiment of the invention are disposed in opposition to each other and the liquid crystal layer 150 is formed between the two substrates 110 and 130, so that the liquid crystal display 100 is manufactured.

Embodiments of the invention may be modified in various ways. For example, the convex pattern formed through the embodiment of FIGS. 1 and 2 may serve as a spacer.

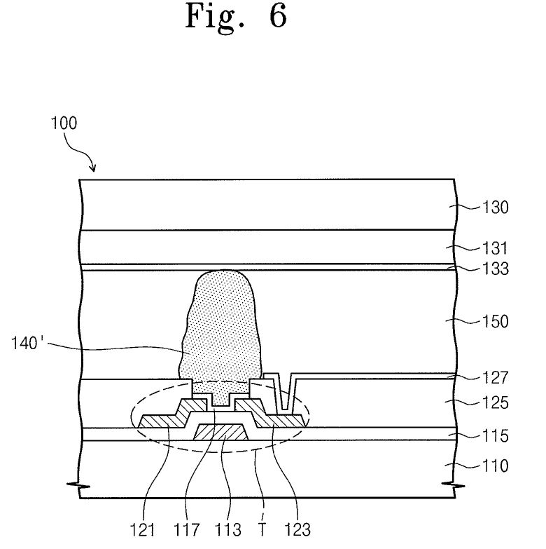

FIG. 6 is a cross sectional view showing a convex pattern serving as a spacer to maintain a cell gap between a first substrate 110 and a second substrate 130. In the following description, the reference numerals used in the first embodiment will be used to refer to the same elements. A spacer 140′ is formed by repeating a process of dropping ink droplets and performing the half-bake.

Although embodiments of the present embodiment have been described with reference to a TN (Twisted Nematic) liquid crystal display for convenience of explanation, embodiments of the present invention are not limited thereto the embodiment, and other embodiments of the present invention are applicable to in plane switching LCDs or a vertical alignment LCDs. In particular, according to another embodiment of the present invention, the convex pattern can be used as an electric field distortion member in a lateral electric field LCD.

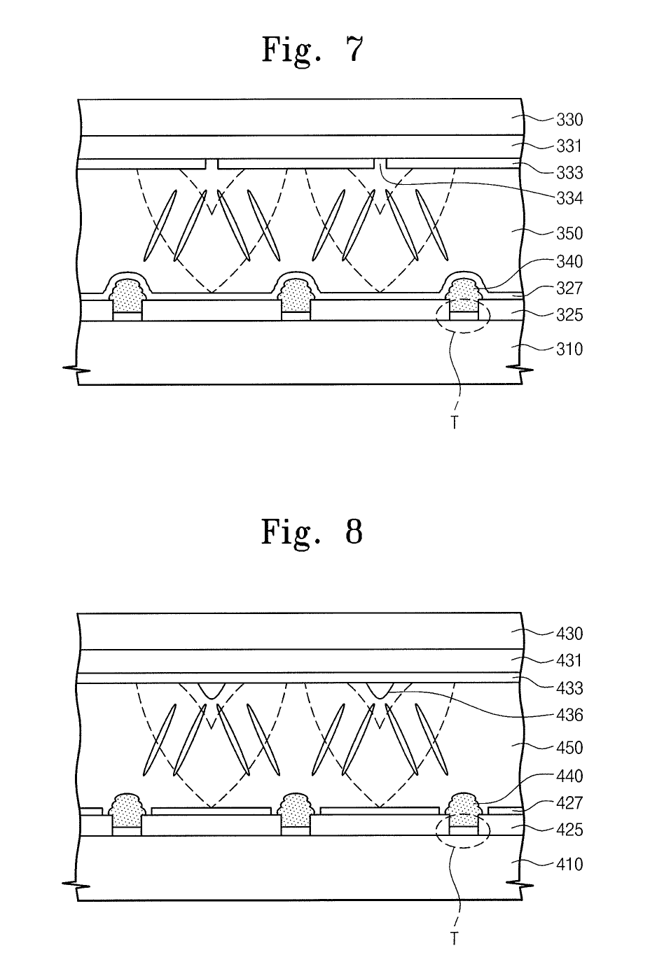

FIGS. 7 and 8 show convex patterns according to other embodiments of the present invention, respectively. For convenience of explanation, a thin film transistor having a semiconductor layer has been schematically illustrated. In the following description, the reference numerals used in the embodiment of FIGS. 1 and 2 will correspond to the reference numerals of the same elements of FIGS. 7 and 8.

As shown in the FIG. 7, a convex pattern 340 serves as a plurality of protrusions, which distorts the electric field generated on a liquid crystal layer 350 of a first substrate 310 to guide a director of the liquid crystal molecules into a desired direction. A pixel electrode 327 used to generate the electric field can be formed on the protrusion. A plurality of slits 334 are formed in a common electrode 333 of a second substrate 330 to distort the electric field.

According to the embodiment depicted in FIG. 8, a convex pattern 440 serves as a plurality of protrusions to distort the electric field in a first substrate 410, and a pixel electrode 427 is not formed on the convex pattern 440. In addition, a common electrode 433 of a second substrate 430 is formed with protrusions 436 instead of slits. The protrusions 436 of the second substrate 430 can be formed through an embodiment of the present invention. In the embodiment shown in FIG. 8, due to the height difference caused by the protrusions 436 and a patterned pixel electrode 427, an effect similar to that caused by a slit can be achieved, so that the liquid crystal can be easily controlled.

Although exemplary embodiments of the present invention have been described, it is understood that the present invention should not be limited to these exemplary embodiments but various changes and modifications can be made by one of ordinary skill in the art within the spirit and scope of the present invention as hereinafter claimed.

What is claimed is:

1. A liquid crystal display comprising:
a first substrate;
a second substrate facing the first substrate;
a thin film transistor on the first substrate, the thin film transistor comprising a semiconductor layer;
a convex pattern on the semiconductor layer, the convex pattern comprising a concave-convex section at a side surface thereof; and
a liquid crystal layer interposed between the first and second substrates.

2. The liquid crystal display of claim 1, wherein the thin film transistor comprises:
a gate electrode on the first substrate;
a gate insulating layer on the gate electrode and the first substrate;
a source electrode and a drain electrode on the gate insulating layer, the source electrode being spaced apart from the drain electrode; and
the semiconductor layer formed on the source and drain electrodes to form a channel between the source and drain electrodes.

3. The liquid crystal display of claim 2, further comprising a bank,
wherein the bank is formed on the gate insulating layer and the source and drain electrodes and has an opening formed at a predetermined region of the source and drain electrodes, and wherein the convex pattern fills the opening.

4. The liquid crystal display of claim 3, further comprising a contact hole through the bank to expose a portion of the remaining region of the drain electrode.

5. The liquid crystal display of claim 4, further comprising:
a pixel electrode on the bank connected to the drain electrode through the contact hole; and
a common electrode on the second substrate to form an electric field in cooperation with the pixel electrode.

6. The liquid crystal display of claim 5, wherein the convex pattern is a protrusion to distort the electric field.

7. The liquid crystal display of claim 6, wherein the common electrode comprises a plurality of slits.

8. The liquid crystal display of claim 6, wherein the common electrode comprises a plurality of protrusions.

9. The liquid crystal display of claim 1, wherein the convex pattern is a spacer to maintain a cell gap between the first and second substrates.

10. A method of manufacturing a liquid crystal display, the method comprising:
preparing a first substrate;
preparing a second substrate facing the first substrate;
forming a thin film transistor comprising a semiconductor layer on the first substrate;
forming a convex pattern on the semiconductor layer; and
interposing a liquid crystal layer between the first and second substrates, wherein the forming of the convex pattern comprises:
dropping a first plurality of ink droplets on the semiconductor layer through an ink-jet scheme;
baking the first plurality of ink droplets to form a first pattern;
dropping a second plurality of ink droplets on the first pattern; and
baking the second plurality of ink droplets to form a second pattern.

11. The method of claim 10, wherein the baking of the first plurality of ink droplets and the second plurality of ink droplets are half-bakes.

12. The method of claim 11, wherein the half-bake is performed under room temperature.

13. The method of claim 11, wherein the half-bake is performed through irradiation of light.

14. The method of claim 11, further comprising repeating the steps of dropping a plurality of ink droplets and the half-baking the dropped ink droplets.

15. The method of claim 10, wherein the forming of the thin film transistor comprises:
forming a gate electrode on the first substrate;
forming a source electrode and a drain electrode spaced apart from the source electrode on the first substrate;
forming a gate insulating layer on the surface of the first substrate forming a bank on the gate insulating layer and a remaining region of the source and drain electrodes, the bank having an opening formed at a predetermined region of the source and drain electrodes; and
forming the semiconductor layer on the source and drain electrodes to form a channel between the source and gate electrodes.

16. A method of manufacturing a liquid crystal display, the method comprising:
forming a thin film transistor comprising a semiconductor layer
forming a convex pattern on the semiconductor layer, wherein the forming of the convex pattern comprises:
dropping a plurality of ink droplets on the semiconductor layer through an ink-jet scheme;
baking the plurality of ink droplets to form a pattern; and
repeating the steps of dropping a plurality of ink droplets and the half-baking the dropped ink droplets to form a pattern, wherein a number of droplets in each plurality of ink droplets may be varied.

17. The method of claim 16, further comprising:
preparing a first substrate;
preparing a second substrate facing the first substrate;
forming said thin film transistor on the first substrate;
interposing a liquid crystal layer between the first and second substrates,
wherein the forming of the thin film transistor comprises:
forming a gate electrode on the first substrate;
forming a source electrode and a drain electrode spaced apart from the source electrode on the first substrate;
forming a gate insulating layer on the surface of the first substrate
forming a bank on the gate insulating layer and a remaining region of the source and drain electrodes, the bank having an opening formed at a predetermined region of the source and drain electrodes; and
forming said semiconductor layer on the source and drain electrodes to form a channel between the source and gate electrodes.
